(19) United States
(12) Patent Application Publication
(10) Pub. No.: US 2012/0126864 A1
(43) Pub. Date: May 24, 2012

(54) POWER-ON RESET

(76) Inventors: Tyler Daigle, Portland, ME (US); Julie Lynn Stultz, Scarborough, ME (US)

(21) Appl. No.: 13/299,728

(22) Filed: Nov. 18, 2011

Related U.S. Application Data
(60) Provisional application No. 61/416,232, filed on Nov. 22, 2010.

(51) Int. Cl. H03L 7/00

(52) U.S. Cl. 327/143

(57) ABSTRACT

This document discusses, among other things, apparatus and methods for providing power-on reset (POR) functionality using an enable circuit. In an example, an apparatus can include a supply input configured to receive a supply voltage, an enable input configured to receive an enable signal, and an inversion network configured to control an enable output using the enable signal. The inversion network can include a delay element configured to delay a first transition of the enable output in response to a rising transition of the supply voltage.

### CLAIM OF PRIORITY

This patent application claims the benefit of priority, under 35 U.S.C. Section 119(e), to Daigle et al., U.S. Provisional Patent Application Ser. No. 61/416,232, entitled “POWER-ON RESET,” filed on Nov. 22, 2010 (Attorney Docket No. 2921.084PRV), which is hereby incorporated by reference herein in its entirety.

### BACKGROUND

A dedicated power-on reset (POR) circuit can be used to disable device circuitry until a device power supply reaches a level sufficient to power the device. However, the dedicated POR circuit can use valuable die area that can otherwise be allocated to circuitry to enhance user experience.

### OVERVIEW

This document discusses, among other things, apparatus and methods for providing power-on reset (POR) functionality using an enable circuit. In an example, an apparatus can include a supply input configured to receive a supply voltage, an enable input configured to receive an enable signal, and an inversion network configured to control an enable output using the enable signal. The inversion network can include a delay block configured to delay a first transition of the enable output in response to a rising transition of the supply voltage.

This section is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example power-on reset (POR) circuit.

FIG. 2 illustrates generally an example power-on sequence of a power-on reset (POR) circuit.

FIG. 3 illustrates generally an example power-on sequence of an enable circuit.

FIG. 4 illustrates generally example hysteresis of a hysteretic comparator.

### DETAILED DESCRIPTION

A traditional power-on reset (POR) circuit can be used to disable device circuitry while a power supply voltage ramps up to an operating voltage. The traditional POR circuit can be used to ensure that circuitry logic commences operation in a known state. The present inventors have recognized, among other things, systems and methods to provide POR functionality using existing circuit components, such as an enable circuit. The improved systems and methods can provide an alternative to a dedicated POR circuit, saving die area and potential power usage by providing multiple functions in a single circuit.

In an example, POR functionality can be added to an enable circuit using a delay block and an inverter, allowing an internal enable signal to provide a POR signal. In certain examples, the POR circuit disclosed herein can include a resistor-capacitor (RC) delay block placed strategically in an inversion chain to allow circuitry coupled to an output of the POR circuit to remain disabled when a supply voltage ramps from zero to a steady state value. When placed in line with an enable/disable logic path, such that the capacitor is discharged when the POR circuit is disabled, the delay block of the inversion network can control an initial state of circuitry coupled to the internal enable signal. In an example, because the capacitor of the delay block can charge as the supply voltage powers up, the inversion network can maintain a state of the internal enable signal, such that circuitry responsive to the internal enable signal can remain disabled.

In certain examples, the inverter chain can include a hysteretic component, such as a hysteretic comparator or inverter having wide-hysteresis inserted, for example, after the RC delay block. Placement of the hysteretic inverter can be configured to increase the efficiency of die area used by the capacitor. Arrangement of the hysteretic inverter after the RC delay block can ensure that the capacitor can charge to a first threshold, or discharge to a second lower threshold, before the output of the hysteretic inverter transitions. This arrangement of the RC delay block and the hysteretic inverter can result in the use of fewer capacitors to create a sufficient delay and can use less current during a transition of the internal enable output.

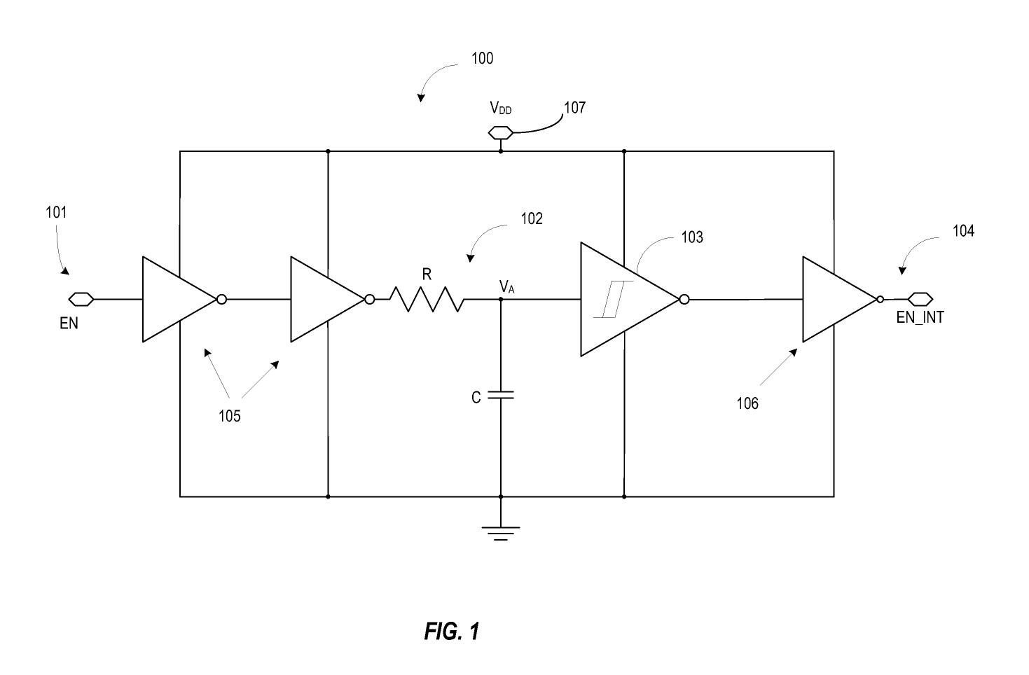

FIG. 1 illustrates generally an example POR circuit 100 configured to provide an enable output and a power-on reset (POR) function. The POR circuit 100 can include a supply input 107 for receiving a supply voltage (V_{DD}), an input 101 to receive an enable signal, a delay block 102 (e.g., including a resistor-capacitor (RC) network), a hysteretic comparator 103, such as an inverter with a hysteresis band, and an output 104. In some examples, one or more input inverters 105 can be arranged before the delay block 102 (e.g., depending on the desired delay, the desired output signal, etc.). In an example, one or more output inverters 106 can be arranged between the output of the hysteretic comparator 103 and the output 104 of the POR circuit 100.

In certain examples, the input 101 can be configured to receive an enable signal (EN) and the output 104 can be configured to provide an internal enable signal (EN_INT) for circuitry coupled to the POR circuit 100. In certain examples, the number of input inverters 105 arranged before the delay block 102 is configured such that a capacitor voltage (V_{A}) of a capacitor (C) of the RC network can be zero volts when the POR circuit 100 is disabled.

In the illustrated circuit of FIG. 1, the output 104 can be configured to disable circuitry coupled to the output 104 when the input 101 is at a low logic level. When the input 101 is at a low logic level, the capacitor (C) can be discharged to zero volts. Upon power-up, the power supply voltage (V_{DD}) can ramp from zero volts and the capacitor (C) can charge. The output of the hysteresis inverter 103 can transition after the capacitor (C) has charged to a first threshold. The first threshold (e.g., defined by the hysteresis of the hysteretic comparator 103) can be selected such that the supply voltage is high enough to support powering at least the circuitry coupled to the output of the hysteretic comparator 103. In an example, the circuitry coupled to the output of the hysteretic comparator 103 can remain disabled through the power-on period of the power supply using the delay caused by the charging of the capacitor (C) of the delay block 102. The delay of the delay block 102 can allow the power supply to reach a voltage state sufficient to power the remaining circuitry coupled to the POR circuit 100 before the rest of the circuit is enabled.

In an example, an integrated circuit (IC) can include the one or more input inverters 105, the hysteretic comparator 103, and the one or more output inverters 106. In certain examples, the IC can include at least a portion of the delay block 102.

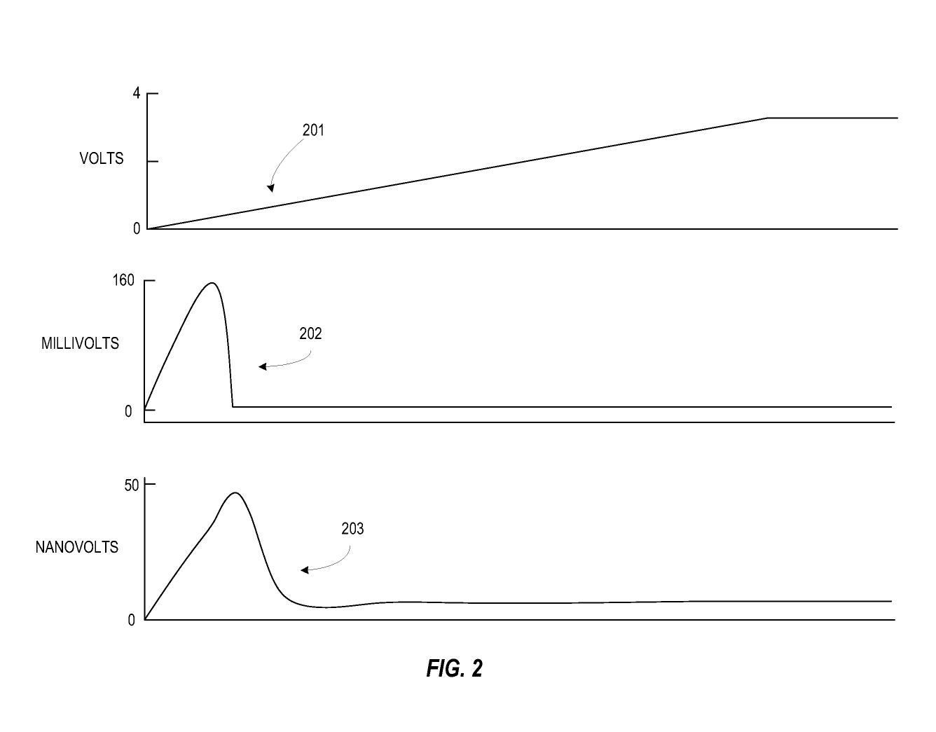

FIG. 2 illustrates generally an example power-on sequence of a POR circuit, such as the POR circuit 100 of FIG. 1, the power-on sequence including a supply voltage (V_{DD}) 201, an output signal 202 (e.g., the internal enable signal (EN_INT) of FIG. 1), and a voltage signal (V_{A}) 203 (e.g., the voltage across the capacitor (C) of the RC network of FIG. 1).

In an example, an enable signal (EN) received at an input of a POR circuit can remain at a low logic level throughout the power-on sequence, indicating that a circuit receiving the output signal 202 can remain disabled. As the supply voltage (V_{DD}) 201 ramps up, the voltage signal (V_{A}) 203 across the capacitor (C) of the RC block can remain substantially discharged and the output signal 202 does not exceed a high logic threshold. In the illustrated example, the voltage signal (V_{A}) 203 and the output signal 202 can rise as the supply voltage (V_{DD}) 201 begins to increase from zero volts. However, the peak of the output and voltage signals 202, 203 can remain significantly below an upper threshold of a hysteretic comparator (e.g., an hysteresis inverter) for the voltage signal (V_{A}) 203 and substantially below a high logic level for the output signal 202.

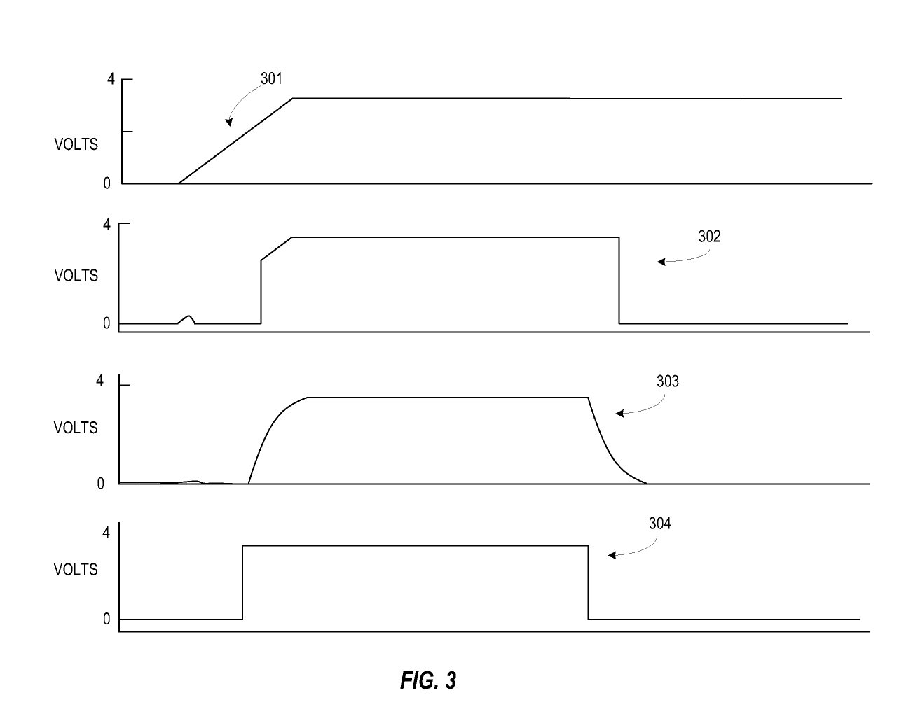

FIG. 3 illustrates generally an example power-on sequence of an enable circuit where an enable signal 304 transitions from a low logic level to a high logic during a ramp-up of a supply voltage (V_{DD}) 301. The plots illustrate the supply voltage 301, an output signal 302 of the enable circuit, a capacitor voltage (V_{A}) 303 of an RC network of the enable circuit, and the enable signal 304 received at the input of the enable circuit. As the supply voltage 301 ramps up, a slight perturbation of the capacitor voltage signal 303 and the output signal 302 can occur, but the perturbation may not be enough to enable circuits receiving the output signal 302. As the enable signal 304 transitions from a low logic level to a high logic level, a capacitor of a delay block of the enable circuit can begin to charge and the capacitor voltage 303 can begin to increase.

As the capacitor voltage 303 increases, the supply voltage 301 can reach a level sufficient to maintain operation of components of the enable circuit as well as other circuits configured to receive the output signal 302 of the enable circuit. As the capacitor voltage 303 reaches an upper threshold of a hysteretic comparator, the output signal 302 of the enable circuit can transition to a high logic level and enable the properly powered circuits configured to receive the output signal 302. In an example, the output signal 302 can track the rising supply voltage signal 301 as it ramps to a steady state level. In an example, an upper hysteresis level of the hysteretic comparator is selected high enough to ensure the supply voltage 301 necessary to properly power electronics associated with the enable circuit is reached before the output signal 302 of the enable circuit transitions from the low logic level to the high logic level.

In an example, in response to the enable signal 304 transitioning from a high logic level to a low logic level, the output signal 302 can transition from a high logic level to a low logic level as the capacitor voltage 303 discharges past a lower hysteresis threshold of the hysteretic comparator. In an example, the transition delay between the high to low transition of the enable signal 304 and the high to low transition of the output signal 302 can be reduced using a NAND gate in place of one or more of the inverters, such as the output inverter 106 of FIG. 1. In such an example, a first input of the NAND gate can receive the output of the hysteretic comparator, a second input of the NAND gate can receive the enable signal 304, and an output of the NAND gate can provide the output signal 302.

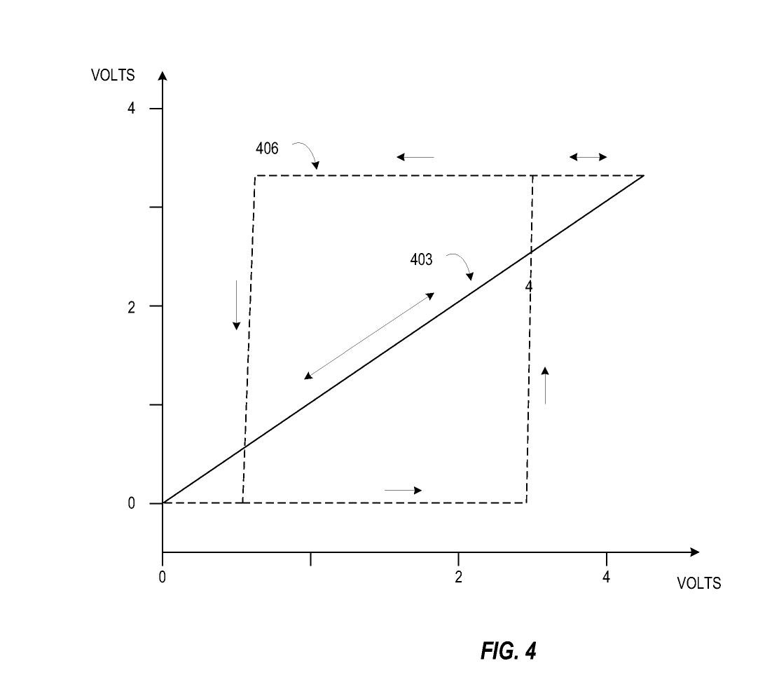

FIG. 4 illustrates generally example hysteresis of a hysteretic comparator, such as the hysteretic comparator 103 of FIG. 1, including an output signal 406 of an example hysteretic inverter with respect to a capacitor voltage (V_{A}) 403 of an RC network, such as the RC network illustrated in FIG. 1. The output signal 406 of the hysteretic inverter can transition from a low logic level to a high logic level when the rising capacitor voltage VA 403 is at about 2.5 volts, for example, depending on the hysteresis thresholds. Similarly, the output signal 406 of the hysteretic inverter can transition from a high logic level to a low logic level when the falling capacitor voltage 403 is at about 0.5 volts, depending on the hysteresis thresholds. In the illustrated example, the inverter can include a hysteresis of about 2 volts. It is understood that other values of hysteresis are possible without departing from the scope of the current subject matter.

### Additional Notes and Examples

In Example 1, an apparatus can include a supply input configured to receive a supply voltage, an enable input configured to receive an enable signal, and an inversion network configured to control an enable output using the enable signal. The inversion network can include a delay block configured to delay a first transition of the enable output in response to a rising transition of the supply voltage.

In Example 2, the delay block of example 1 optionally includes a capacitor; is optionally configured to delay the first transition of the enable output using the capacitor.

In Example 3, the delay block of any one or more of Examples 1-2 optionally includes a resistor-capacitor circuit, and the delay block of any one or more of Examples 1-2 is optionally configured to delay the first transition of the enable output using the resistor-capacitor circuit.

In Example 4, the inversion network of any one or more of Examples 1-3 optionally includes a first inverter configured to receive the enable signal and a second inverter configured to receive an output of the first inverter and to provide an output to the delay block.

In Example 5, the inversion network of any one or more of Examples 1-4 optionally includes a hysteretic comparator configured to receive an output of the delay block and to provide a hysteretic output signal.

In Example 6, the hysteretic comparator of any one or more of Examples 1-5 optionally includes a hysteretic inverter.

In Example 7, the inversion network of any one or more of Examples 1-6 optionally includes a third inverter configured to receive the hysteretic output signal and to provide the enable output.

In Example 8, the inversion network of any one or more of Examples 1-7 optionally includes a hysteretic comparator configured to receive an output of the delay block and to provide a hysteretic output signal.

In Example 9, the hysteretic comparator of any one or more of Examples 1-8 optionally includes a hysteretic inverter.

In Example 10, the inversion network of any one or more of Examples 1-9 optionally includes a first inverter configured to receive the enable signal and a second inverter configured to receive an output of the first inverter and to provide an output to the delay block.

In Example 11, a method can include receiving a supply voltage, receiving an enable signal, controlling an enable output using an inversion network and the enable signal, and delaying a first transition of the enable output using a delay block in response to a rising transition of the supply voltage.

In Example 12, delaying a first transition of any one or more of Examples 1-11 optionally includes delaying a transition of the enable output until after a rising transition of the supply voltage reaches a level configured to power circuitry configured to receive the enable output.

In Example 13, the method of any one or more of Examples 1-12 optionally includes delaying a second transition of the enable output in response to a transition of the enable input.

In Example 14, the providing an enable signal of any one or more of Examples 1-13 optionally includes transitioning the enable output from a first state to a second state at a first threshold, and transitioning the enable output from the second state to the first state at a second threshold, wherein the second threshold is different from the first threshold.

In Example 15, the delaying the first transition of any one or more of Examples 1-14 optionally includes charging a capacitor using the enable signal.

In Example 16, the delaying the first transition of any one or more of Examples 1-15 optionally includes discharging a capacitor using the enable signal.

In Example 17, a power-on reset circuit can include a supply input configured to receive a supply voltage, an enable input configured to receive an enable signal, and an inversion network configured to control an enable output using the enable signal. The inversion network can include a delay block configured to delay a first transition of the enable output in response to a rising transition of the supply voltage, wherein the delay block includes a resistor-capacitor network, a first inverter configured to receive the enable signal, a second inverter configured to receive an output of the first inverter and to provide an output to the delay block, a hysteretic comparator configured to receive an output of the delay block and to provide a hysteretic output signal, and a third inverter configured to receive the hysteretic output signal and to provide the enable output.

Example 18 can include, or can optionally be combined with any portion or combination of any portions of any one or more of Examples 1-17 to include, subject matter that can include means for performing any one or more of the functions of Examples 1-17, or a machine-readable medium including instructions that, when performed by a machine, cause the machine to perform any one or more of the functions of Examples 1-17.

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. In other examples, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. An apparatus comprising:
a supply input configured to receive a supply voltage;
an enable input configured to receive an enable signal;
an inversion network configured to control an enable output using the enable signal, wherein the inversion network includes:
a delay block configured to delay a first transition of the enable output in response to a rising transition of the supply voltage.

2. The apparatus of claim 1, wherein the delay block includes a capacitor; and
wherein the delay block is configured to delay the first transition of the enable output using the capacitor.

3. The apparatus of claim 2, wherein the delay block includes a resistor-capacitor circuit; and
wherein the delay block is configured to delay the first transition of the enable output using the resistor-capacitor circuit.

4. The apparatus of claim 3, wherein the inversion network includes:
a first inverter configured to receive the enable signal; and
a second inverter configured to receive an output of the first inverter and to provide an output to the delay block.

5. The apparatus of claim 4, wherein the inversion network includes a hysteretic comparator configured to receive an output of the delay block and to provide a hysteretic output signal.

6. The apparatus of claim 5, wherein the hysteretic comparator includes a hysteretic inverter.

7. The apparatus of claim 6, wherein the inversion network includes a third inverter configured to receive the hysteretic output signal and to provide the enable output.

8. The apparatus of claim 1, wherein the inversion network includes a hysteretic comparator configured to receive an output of the delay block and to provide a hysteretic output signal.

9. The apparatus of claim 8, wherein the hysteretic comparator includes a hysteretic inverter.

10. The apparatus of claim 9, wherein the inversion network includes:
a first inverter configured to receive the enable signal; and
a second inverter configured to receive an output of the first inverter and to provide an output to the delay block.

11. A method comprising:
receiving a supply voltage;
receiving an enable signal;
controlling an enable output using an inversion network and the enable signal; and
delaying a first transition of the enable output using a delay block in response to a rising transition of the supply voltage.

12. The method of claim 11, wherein delaying a first transition includes delaying a transition of the enable output until after a rising transition of the supply voltage reaches a level configured to power circuitry configured to receive the enable output.

13. The method of claim 11, including delaying a second transition of the enable output in response to a transition of the enable input.

14. The method of claim 11, wherein the providing an enable signal includes transitioning the enable output from a first state to a second state at a first threshold; and
transitioning the enable output from the second state to the first state at a second threshold, wherein the second threshold is different from the first threshold.

15. The method of claim 11, wherein delaying the first transition includes charging a capacitor using the enable signal.

16. The method of claim 11, wherein delaying the first transition includes discharging a capacitor using the enable signal.

17. A power-on reset circuit comprising:
a supply input configured to receive a supply voltage;
an enable input configured to receive an enable signal; and
an inversion network configured to control an enable output using the enable signal, wherein the inversion network includes:
a delay block configured to delay a first transition of the enable output in response to a rising transition of the supply voltage, wherein the delay block includes a resistor-capacitor network;
a first inverter configured to receive the enable signal;
a second inverter configured to receive an output of the first inverter and to provide an output to the delay block;
a hysteretic comparator configured to receive an output of the delay block and to provide a hysteretic output signal; and
a third inverter configured to receive the hysteretic output signal and to provide the enable output.
